(19) United States
(12) Patent Application Publication
(10) Pub. No.: US 2023/0163242 A1
(43) Pub. Date: May 25, 2023

(54) LED STRUCTURE, INK FOR INKJET AND LIGHT SOURCE COMPRISING THE SAME

(71) Applicant: KOOKMIN UNIVERSITY INDUSTRY ACADEMY COOPERATION FOUNDATION, Seoul (KR)

(72) Inventor: Young Rag DO, Seoul (KR)

(73) Assignee: KOOKMIN UNIVERSITY INDUSTRY ACADEMY COOPERATION FOUNDATION, Seoul (KR)

(21) Appl. No.: 18/049,705

(22) Filed: Oct. 26, 2022

(30) Foreign Application Priority Data
Oct. 26, 2021 (KR) 10-2021-0143366

(51) Int. Cl. H01L 33/20

(52) U.S. Cl. CPC H01L 33/20; H01L 33/325

(57) ABSTRACT

The present invention relates to an LED structure, more particularly, to an LED structure and an ink for inkjet and light source including the same.

### BACKGROUND OF THE INVENTION

### Field of the Invention

The present invention relates to an LED structure, more particularly, to an LED structure and an ink for inkjet and light source including the same.

### Description of the Related Art

LEDs and nano-LEDs may implement an excellent feeling of color and high efficiency and may be eco-friendly materials, thereby being used as core materials for displays. In line with such market conditions, recently, research for developing new nanorod LED structures or shell-coated nano-cable LEDs through new manufacturing processes is being carried. In addition, research on a protective film material is being carried out to achieve high efficiency and high stability of a protective film covering an outer surface of nanorods, and research and development of a ligand material advantageous for a subsequent process are also being carried out.

Recently, large-sized red, green, and blue micro-LED display TVs have been commercialized in line with research in such material fields, and in the future, TVs, which implement full-color through blue subpixels implemented using blue micro-LEDs or nano-LEDs and red and green subpixels implemented using quantum dots emission through the blue LEDs, will be commercialized. In addition, red, green, and blue nano-LED display TVs will also be commercialized.

Micro-LED displays have advantages such as high performance characteristics, very long theoretical lifetime, and very high efficiency, but when micro-LED displays are developed as displays with 8K resolution, a red micro-LED, a green micro-LED, and a blue micro-LED should be put in one-to-one correspondence with each of nearly 100 million subpixels. Thus, through pick and place technology for manufacturing micro-LED displays, it is difficult to manufacture true high-resolution commercial displays ranging from smartphones to TVs due to the limitations of process technology, considering a high unit price, a high process defect rate, and low productivity. In addition, it is more difficult to individually arrange nano-LEDs on subpixels using pick and place technology for micro-LEDs.

In order to overcome such difficulty, Korean Patent Registration No. 10-1436123 discloses a display manufactured through a method of dropping a solution mixed with nanorod-type LEDs on subpixels and then forming an electric field between two alignment electrodes to self-align nanorod-type LED elements on the electrodes and form the subpixels.

However, in the disclosed technology, since the LED elements are aligned through an electric field, the LED elements should have a rod-like shape that is formed to be elongated in one direction and has a large aspect ratio. Thus, the LED elements are easily precipitated in a solvent and thus are difficult to form into ink. In addition, since the elements lie down to be assembled on the electrodes, that is, are assembled to be parallel to a stack direction of each semiconductor layer in the element, the area from which light is extracted is small, which causes a problem in that efficiency is not high.

In addition, when power is applied to the electrodes to align the LED elements through an electric field, the electrodes may be damaged by a high voltage power source.

Furthermore, other methods for self-aligning micro-LED elements, for example, a method using magnetic force, etc. have been recently introduced. However, for this purpose, additional processing such as having a magnetic layer on the LED element is required for the LED element, and a separate device for generating a magnetic field is also required, which may cause problems of increasing the manufacturing cost, time of the LED elements, and cost for self-alignment of the LED element.

Therefore, there is an urgent need to develop a new LED material that has a wide emission area, minimizes or prevents a decrease in efficiency due to surface defects, has an optimized electron-hole recombination rate, is suitable for inking, and self-aligns so that desired surface contacts easily on electrodes without a difficult additional process for self-alignment.

### SUMMARY OF THE INVENTION

The present invention is designed to solve the above problems, and an object of the present invention is to provide an LED structure which has a large emission area, minimizes or prevents efficiency degradation due to surface defects, optimizes the recombination rate of electron-holes, and is suitable for inking, is self-aligned so that a desired surface is in contact easily on an electrode without a difficult additional process for self-alignment, and an ink for inkjet including the same, a display manufactured through the LED structure, and various light sources such as display, lighting.

Meanwhile, it is informed that the present invention has been researched with the support of the following national R&D projects.
[Project Number] 421036031HD030
[Government Department Name] Ministry of Agriculture, Food and Rural Affairs
[Project Management (Specialized) Authority Name] Agriculture, Forestry and Food Technology Planning and Evaluation Institute
[Research Program Name] Smart Farm Multi-Ministry Package Innovative Technology Development (R&D)
[Research Project Name] Development of dichroic optical filter customized for crop growth for greenhouses
[Contribution Rate] 1/1
[Project Execution Organization Name] Kookmin University Industry Academic Cooperation
[Research Period] 2021.04.01 to 2023.12.31

In order to achieve the above object, the present invention provides an LED structure in which layers comprising a first conductive semiconductor layer, a photoactive layer, and a second conductive semiconductor layer are stacked, wherein in order that any one of two opposite target surfaces of the LED structure perpendicular to a stacking direction of the layers becomes a contact surface with respect to a ground when the LED structure is freely precipitated, a ratio S/t of an area S (µm²) of any one of the target surfaces and a distance t (µm) between the two target surfaces satisfies 1.5 or more.

According to one embodiment of the present invention, one of the first conductive semiconductor layer and the second conductive semiconductor layer may be an n-type III-nitride semiconductor layer, and the other one may be a p-type III-nitride semiconductor layer.

In addition, when one of the two target surfaces is a first target surface and the other is a second target surface, an area ratio of the first target surface and the second target surface may be 1:0.1 to 10.

In addition, the areas of the two target surfaces may be each independently 0.2 to 100 µm².

In addition, the distance t between the two target surfaces may be 0.3 to 3.5 µm.

In addition, the first conductive semiconductor layer may be an n-type III-nitride semiconductor layer, and the LED structure may further include an electron delay layer below the first conductive semiconductor layer so that numbers of electrons and holes recombined in the photoactive layer are balanced.

In addition, the electron delay layer may include at least one selected from the group consisting of CdS, GaS, ZnS, CdSe, CaSe, ZnSe, CdTe, GaTe, SiC, ZnO, ZnMgO, SnO₂, TiO₂, In₂O₃, Ga₂O₃, silicon (Si), poly(paraphenylene vinylene) and derivatives thereof, polyaniline, poly(3-alkylthiophene), and poly(paraphenylene).

In addition, the first conductive semiconductor layer may be a doped n-type III-nitride semiconductor layer, and the electron delay layer may be a III-nitride semiconductor having a doping concentration lower than that of the first conductive semiconductor layer.

In addition, the LED structure may further include a protective film configured to surround an exposed side surface of the LED structure.

In addition, the first conductive semiconductor layer may be an n-type III-nitride semiconductor layer, the second conductive semiconductor layer may be a p-type III-nitride semiconductor layer, and wherein the LED structure may further include at least any one film of a hole pushing film configured to surround an exposed side surface of the second conductive semiconductor layer or the exposed side surface of the second conductive semiconductor layer and an exposed side surface of at least a portion of the photoactive layer and move holes at a surface side of the exposed side surface toward a center, and an electron pushing film configured to surround an exposed side surface of the first conductive semiconductor layer and move electrons at a surface side of the exposed side surface toward a center.

In addition, the LED structure may include both the hole pushing film and the electron pushing film, the electron pushing film may be provided as an outermost film configured to surround side surfaces of the first conductive semiconductor layer, photoactive layer, and second conductive semiconductor layer.

In addition, the hole pushing film may include at least one selected from the group consisting of AlNₓ, ZrO₂, MoO, Sc₂O₃, La₂O₃, MgO, Y₂O₃, Al₂O₃, Ga₂O₃, TiO₂, ZnS, Ta₂O₅, and n-MoS₂.

In addition, the electron pushing film may include at least one selected from the group consisting of Al₂O₃, HfO₂, SiNₓ, SiO₂, ZrO₂, Sc₂O₃, AlNₓ, and Ga₂O₃.

In addition, the LED structure may further include a second electrode layer provided on the first conductive semiconductor layer and a first electrode layer provided on the second conductive semiconductor layer.

In addition, the LED device may further include a selective bonding layer configured to erect and assemble the LED structure in a thickness direction thereof at a desired position of a driving electrode on an uppermost layer or a lowermost layer of the LED structure, wherein the selective bonding layer may be a magnetic layer or a chemical bond inducing layer.

In addition, the present invention provides an ink composition for inkjet, including a plurality of the LED structures according to the present invention.

In addition, the present invention provides a light source which is equipped with the LED structure according to the present invention.

Hereinafter, the terms used in the present invention will be defined.

In descriptions of embodiments of the present invention, it should be understood that when a layer, region, pattern, or substrate is referred to as being formed “on,” “upper”, “above,” “under,” “lower”, “below” another layer, another region, or another pattern, the terminology of “on,” “upper”, “above,” “under,” “lower”, “below” includes both the meanings of “directly” and “indirectly”.

### BRIEF DESCRIPTION OF THE DRAWINGS

FIG. 1 is a perspective view of an LED structure according to an embodiment of the present invention.

FIG. 2 is a cross-sectional view taken along the boundary line X-X′ of FIG. 1 .

FIGS. 3A to 3C are perspective views of an LED structure according to various embodiments of the present invention.

FIG. 4 is a schematic view for describing a balance of electrons and holes in an LED device.

FIG. 5 is a perspective view of an LED structure according to an embodiment of the present invention.

FIG. 6 is a cross-sectional view of an LED structure according to an embodiment of the present invention.

FIGS. 7 to 9 are schematic views of a method for manufacturing an LED structure according to various embodiments of the present invention.

FIG. 10 are views illustrating a state in which precipitated LED structures are aligned on an electrode after an ink composition containing LED structures according to an embodiment of the present invention is treated on the electrode.

FIG. 11 is a view illustrating that some LED structures are aligned on an electrode in FIG. 10 (b).

FIGS. 12A and 12B are SEM pictures of the LED structure according to Example 1.

### DETAILED DESCRIPTION OF THE INVENTION

Hereinafter, embodiments of the present invention will be described in detail with reference to the accompanying drawings such that those skilled in the art to which the present invention can easily carry out the present invention. It should be understood that the present invention may be embodied in various different forms and is not limited to the following embodiments.

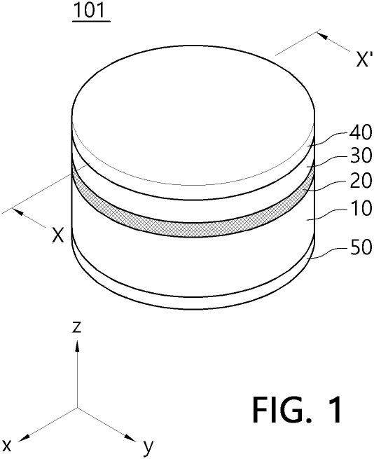

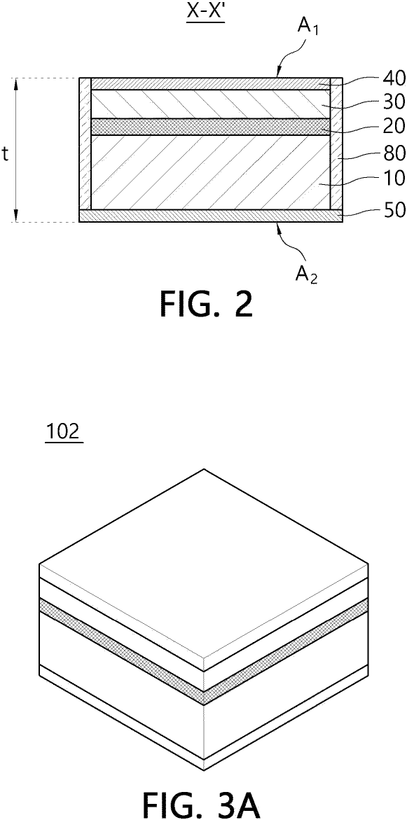

Referring to FIGS. 1 and 2, an LED structure 101 according to the present invention is a structure in which layers including a first conductive semiconductor layer 10, a photoactive layer 20, and a second conductive semiconductor layer 30 are stacked.

The LED structure 101 may be implemented to have a ratio S/t of an area S (µm²) of a target surface A₁ or A₂ and a distance t (µm) between the two target surfaces A₁, A₂ of 1.5 or more, preferably 2.25 or more, more preferably, 3.0 to 20.0 so that when the LED structure is freely precipitated, one of two opposing target surfaces A₁, A₂ of the LED structure 101 corresponding to the x-y plane perpendicular to the z-axis, which is the stacking direction of the layers, becomes a contact surface with respect to the ground. Here, the ground refers to one surface of a predetermined target to which the LED structure, which is precipitated in the liquid, finally comes into contact, and may be, for example, one surface of the electrode. In addition, when the two target surfaces A₁, A₂ have different areas, the area S of the target surface A₁, A₂ is the smaller area of the areas of the two target surfaces A₁, A₂.

Since the ratio S/t satisfies 1.5 or more, when the LED structure touches the ground after free precipitation in the liquid, the probability that any one target surface A₁ or A₂ in the structure will touch the ground is very high. Also, even if a surface other than the target surface A₁ or A₂ touches the ground, the structure spontaneously falls so that either target surface A₁ or A₂ touches the ground due to physical contact that occurs during contact with the ground or either target surface A₁ or A₂ easily touches the ground even with a weak vibration, which is very advantageous for aligning the LED structure 101 to contact the ground. In addition, the fact that the ratio S/t is 1.5 or more means that most of the area of the photoactive layer 20 that determines the emission area of the LED structure in consideration of the stacking direction of the layers corresponds to the target surface, and that as the exposed side area of the photoactive layer 20 corresponding to the remaining surface is implemented to be relatively small, more light is emitted in the direction perpendicular to the target surface, which can improve the front luminance of the light source implemented using this. In addition, the fact that the target surface of the photoactive layer 20 is larger than the exposed side area of the photoactive layer 20 means that the distance between the two target surfaces of the photoactive layer 20, that is, the thickness is implemented to be thin. In this case, the occurrence of defects on the side surface that occurs when an LED wafer is etched in the thickness direction can be lowered, so that there is an advantage that can improve the luminous efficiency.

In the above-described LED structure 101, the areas of the two target surfaces A₁, A₂ may be each independently 0.2 to 100 µm², and the distance t between the two target surfaces A₁, A₂ may be 0.3 to 3.5 µm. Through this, it may be advantageous to achieve the object of the present invention. In particular, manufacturing a device so that the distance between the two target surfaces A₁, A₂ is shorter than 3.5 µm can greatly reduce the movement distance of holes and electrons passing through the p-type semiconductor layer and the n-type semiconductor layer. Therefore, in particular, since not only electrons but also holes with very low mobility can move a shorter distance when moving, loss due to movement can be minimized, thereby greatly improving luminous efficiency. However, when the distance t between the two target surfaces A₁, A₂ is less than 0.3 µm, the thickness of the n-type semiconductor layer may be relatively thinner than that of the p-type semiconductor layer. Due to this, the position where the hole and the electron are combined may deviate from the photoactive layer, and there is a risk that the luminous efficiency is greatly reduced.

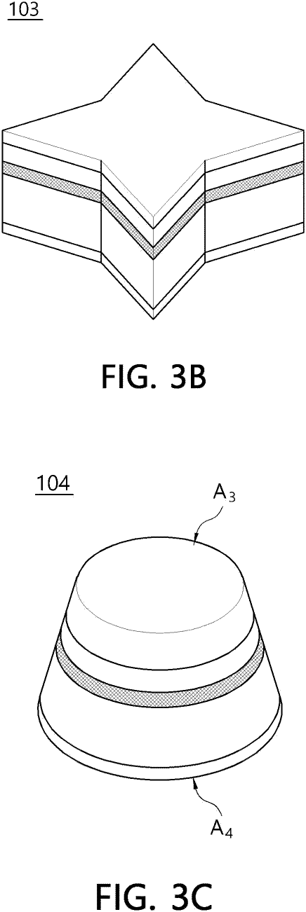

In addition, referring to FIGS. 1, 3a, and 3b, the shape of the target surfaces A₁,A₂ of the LED structure 101, 102, 103 may be a standardized shape such as a circular as illustrated in FIG. 1 or square as illustrated in FIG. 3a, that is, a circle, an ellipse, a rectangle, a rhombus, and the like. However, the present invention is not limited thereto, and may be an irregular polygon or a closed curve as illustrated in FIG. 3b.

In addition, as illustrated in FIG. 1, the area of each of the two target surfaces A₁, A₂ of the LED structure 101 may be the same, but is not limited thereto. The two target surfaces A₁, A₂ of the LED structure 104 may have different areas, as illustrated in FIG. 3c. In this case, when one of the two target surfaces A₃, A₄ is a first target surface A₃ and the other is a second target surface A₄, the area ratio of the first target surface A₃ and the second target surface A₄ may be 1:0.1 to 10, which may be more advantageous in that the target surface becomes a contact surface with the ground during free precipitation. When the area ratio is out of the above area ratio range, even if any one of the target surfaces touches the ground, the LED structure may easily fall sideways due to a weak physical external force and the side surface may touch the ground.

Meanwhile, in the case of the LED structure 101 according to an embodiment of the present invention, as the area S of the target surface A₁ or A₂ is implemented to be greater than the distance t between the two target surfaces A₁, A₂, as described above, the thickness, which is the distance t between the two target surfaces A₁, A₂ can be implemented to be thin. In this case, the possibility that the position where the coupling between the electrons and the holes is formed according to the non-uniform velocity between the electrons and the holes is more likely to leave the photoactive layer 20 is high, so that there is a risk of resulting in a degradation in luminous efficiency. That is, when a large-area LED wafer is etched to implement the LED structures, the thicknesses of the first conductive semiconductor layer, photoactive layer, and second conductive semiconductor layer are already determined in a state of the LED wafer. On the other hand, only portions of the LED structure are etched to a thickness different from that of the wafer and implemented as an LED structure, so this problem inevitably occurs. Such a change in the position at which electrons and holes are combined is caused due to a difference in velocity between electrons and holes moving in conductive semiconductor layers, and for example, in an n-type GaN conductive semiconductor layer, electrons have a mobility of 200 cm²/Vs, and in a p-type GaN conductive semiconductor layer, holes have a mobility of only 5 cm²/Vs. Due to this electron-hole velocity imbalance, the bonding position of electrons and holes varies depending on the thicknesses of the p-type GaN conductive semiconductor layer and n-type GaN conductive semiconductor layer, and the bonding position may leave the photoactive layer.

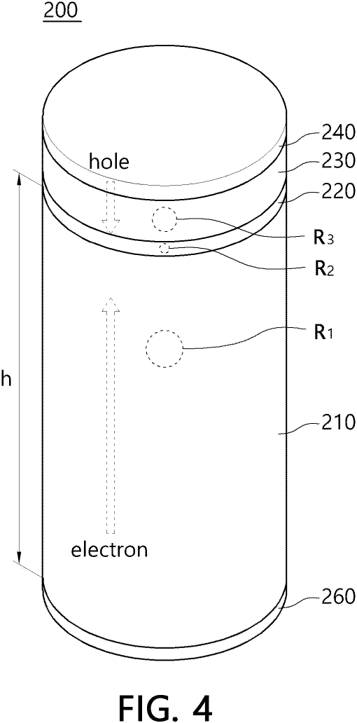

Describing this with reference to FIG. 4, in an LED structure 200 having a diameter of about 600 nm in which an n-type GaN conductive semiconductor layer 210, a photoactive layer 220, and a p-type GaN conductive semiconductor layer 230 are stacked, in consideration of electron mobility of the n-type GaN conductive semiconductor layer 210 and hole mobility of the p-type GaN conductive semiconductor layer 230, when a thickness is designed to balance the numbers of electrons and holes recombined at a point R₂ in the photoactive layer 220, a thickness h of the n-type GaN conductive semiconductor layer 210 inevitably needs to be thick, and thus, unless a thickness of the p-type GaN-conductive semiconductor layer 230 is implemented to be very thin, the rod-type LED structure is very likely to be implemented. In other words, in the case of an LED structure in which the thickness of each layer is designed so that a position where the number of recombination electrons and holes is balanced is a certain point (R2) in the photoactive layer 220, there is a limit to reducing the thickness of the conductive semiconductor layer 230 of p-type GaN, and thus, the conductive semiconductor layer 210 of n-type GaN will be implemented to occupy a large thickness. Accordingly, unless the diameter of the target surface of the LED structure 200 is increased, a rod-type device having a large thickness h of the LED structure 200 is inevitably implemented. Due to this, even if the number of recombined holes and electrons in the photoactive layer is balanced, it is difficult for the target surface to become a contact surface with the ground during free fall or free precipitation. In addition, when the thickness of the conductive semiconductor layer 210 of n-type GaN is implemented to be thin in order to decrease the thickness of the LED structure 200 so that the target surface becomes a contact surface with the ground during free fall or free precipitation, a position where the number of recombined electrons and holes is balanced may be made at any point R₃ in the conductive semiconductor layer 230 of p-type GaN, so that luminous efficiency may be reduced.

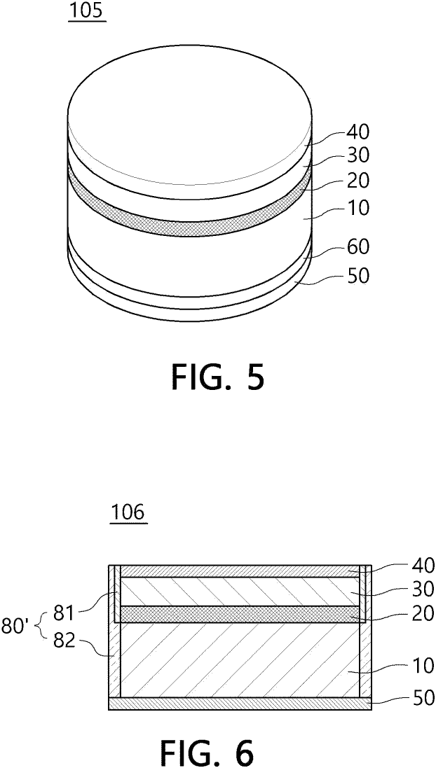

In order to solve this problem, an LED structure according to one embodiment of the present invention may have a suitable geometry so that the target surface becomes a contact surface with the ground during free precipitation, and also may further include an electron delay layer adjacent to an n-type conductive semiconductor layer so as to balance the numbers of holes and electrons recombined in a photoactive layer to prevent a degradation in luminous efficiency. Describing this with reference to FIG. 5, when the first conductive semiconductor layer 10 is an n-type conductive semiconductor, an LED structure 105 may include an electron delay layer 60 below the first conductive semiconductor layer 10. Accordingly, even when a thickness of the first conductive semiconductor layer 10, which is the n-type semiconductor layer, is implemented to be thin, it is possible to prevent a degradation in luminous efficiency. In addition, the decreased thickness of the first conductive semiconductor layer 10 may decrease the probability that electrons are captured by surface defects while moving in a thickness direction of the first conductive semiconductor layer 10, thereby minimizing emission loss.

The electron delay layer 60 may include, for example, at least one selected from the group consisting of CdS, GaS, ZnS, CdSe, CaSe, ZnSe, CdTe, GaTe, SiC, ZnO, ZnMgO, SnO₂, TiO₂, In₂O₃, Ga₂O₃, silicon (Si), poly(paraphenylene vinylene) and derivatives thereof, polyaniline, poly(3-alkylthiophene), and poly(paraphenylene). In addition, the thickness of the electron delay layer 60 may be 1 to 100 nm, but is not limited thereto, and may be appropriately changed in consideration of the material of the n-type conductive semiconductor layer, the material of the electron delay layer, and the like.

Hereinafter, each layer of the LED structure 101, 102, 103, 104, 105 according to an embodiment of the present invention will be described in detail.

Any one of the first conductive semiconductor layer 10 and the second conductive semiconductor layer 30 may be an n-type semiconductor layer, and the other one thereof may be a p-type semiconductor layer. A known semiconductor layer applied to a light emitting diode may be used as the n-type semiconductor layer and the p-type semiconductor layer without limitation. As an example, the n-type semiconductor layer and the p-type semiconductor layer may include Group III-V semiconductors referred to as III-nitride materials, in particular binary, ternary, and quaternary alloys of gallium, aluminum, indium, and nitrogen.

As an example, the first conductive semiconductor layer 10 may be an n-type semiconductor layer. In this case, the n-type semiconductor layer may include a semiconductor material having an empirical formula of InₓAl_{y}Ga_{1-x-y}N (0≤x≤1, 0≤y≤1, 0≤x+y≤1), for example, at least one selected from among InAlGaN, GaN, AlGaN, InGaN, AN, InN, and the like and may be doped with a first conductive dopant (for example, Si, Ge, or Sn). According to one preferred embodiment of the present invention, the first conductive semiconductor layer 10 may have a thickness of 100 to 3,000 nm, but the present invention is not limited thereto.

In addition, the second conductive semiconductor layer 30 may be a p-type semiconductor layer. In this case, the p-type semiconductor layer may include a semiconductor material having an empirical formula of InₓAl_{y}Ga_{1-x-y}N (0≤x≤1, 0≤y≤1, 0≤x+y≤1), for example, at least one selected from among InAlGaN, GaN, AlGaN, InGaN, AlN, and InN, and the like, and may be doped with a second conductive dopant (for example, Mg). According to one preferred embodiment of the present invention, the second conductive semiconductor layer 30 may have a thickness of 50 to 150 nm, but the present invention is not limited thereto.

In addition, the photoactive layer 20 positioned between the first conductive semiconductor layer 10 and the second conductive semiconductor layer 30 may be formed to have a single or multi-quantum well structure. A photoactive layer included in a typical LED device used for a light, a display, and the like may be used as the photoactive layer 20 without limitation. A clad layer (not shown) doped with a conductive dopant may be formed on and/or below the photoactive layer 20, and the clad layer doped with the conductive dopant may be implemented as an AlGaN layer or an InAlGaN layer. In addition, a material such as AlGaN or AlInGaN may be used for the photoactive layer 20. In the photoactive layer 20, when an electric field is applied to a device, electrons and holes moving from the conductive semiconductor layers positioned on and below the photoactive layer to the photoactive layer are combined to generate electron-hole pairs in the photoactive layer, thereby emitting light. According to one preferred embodiment of the present invention, the photoactive layer 20 may have a thickness of 50 to 200 nm, but the present invention is not limited thereto.

Meanwhile, a second electrode layer 50 may be provided below the first conductive semiconductor layer 10. Alternatively, the electron delay layer 60 may be further provided between the first conductive semiconductor layer 10 and the second electrode layer 60. In addition, a first electrode layer 40 may be provided on the second conductive semiconductor layer 30.

An electrode layer included in a typical LED device used for a light, a display, and the like may be used as the first electrode layer 40 and the second electrode layer 50 without limitation. The first electrode layer 40 and the second electrode layer 50 are each independently a single layer made of one selected from among Cr, Ti, Al, Au, Ni, ITO, and oxides or alloys thereof, a single layer made of two or more thereof, or a composite layer in which two or more materials thereof each constitute a layer. As an example, the LED structure may include a first electrode layer in which an ITO layer and a Ti/Au composite layer are stacked on the second conductive semiconductor layer 30. In addition, the first electrode layer 40 and the second electrode layer 50 may each independently have a thickness of 10 to 500 nm, but the present invention is not limited thereto.

In addition, when a surface parallel to the stack direction refers to a side surface, the LED structure 101 may further include a protective film 80 surrounding the side surface of the structure. The protective film 80 performs a function of protecting surfaces of the first conductive semiconductor layer 10, photoactive layer 20, and second conductive semiconductor layer 30. In addition, as in one manufacturing method to be described below, in a process of etching an LED wafer in a thickness direction thereof and then separating a plurality of LED pillars, the protective film 80 may perform a function of protecting the first conductive semiconductor layer 10. The protective film 80 may include, for example, at least one selected from among silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), titanium dioxide (TiO₂), aluminum nitride (AlN), and gallium nitride (GaN). The protective film 80 may have a thickness of 5 to 100 nm and more preferably a thickness of 30 to 100 nm, which may be advantageous in protecting the first conductive semiconductor layer 10 in the process of separating the LED pillars to be described below.

Meanwhile, as illustrated in FIG. 6, an LED structure 106 according to one embodiment of the present invention may include a protective film 80′ which includes a hole pushing film 81 configured to surround an exposed side surface of the second conductive semiconductor layer 30 or the exposed side surface of the second conductive semiconductor layer 30 and an exposed side surface of at least a portion of a photoactive layer 20 and move holes at a surface side of the exposed side surface toward a center, and an electron pushing film 82 configured to surround an exposed side surface of a first conductive semiconductor layer 10 and move electrons at a surface side of the exposed side surface toward a center in order to have a protective function as a protective film and also have more improved luminous efficiency.

Some of the electric charges moving from the first conductive semiconductor layer 10 to the photoactive layer 20 and some of holes moving from the second conductive semiconductor layer 30 to the photoactive layer 20 may move along a surface of a side surface, and in this case, quenching of electrons or holes may occur due to defects present on the surface, which may cause a risk in which luminous efficiency is degraded. In this case, even when a protective film is provided, there is a problem in that quenching is unavoidable due to defects occurring on a device surface before the protective film is provided. However, when the protective film 80′ includes the hole pushing film 81 and the electron pushing film 82, electrons and holes may be concentrated toward a device center and guided to move in a direction of the photoactive layer, and thus, even when defects are present on the device surface before the protective film is formed, there is an advantage in that loss of luminous efficiency due to surface defects can be prevented.

The hole pushing film 81 may include, for example, at least one selected from the group consisting of AlNₓ, ZrO₂, MoO, Sc₂O₃, La₂O₃, MgO, Y₂O₃, Al₂O₃, Ga₂O₃, TiO₂, ZnS, Ta₂O₅, and n-MoS₂, and the electron pushing film 82 may include at least one selected from the group consisting of Al₂O₃, HfO₂, SiNₓ, SiO₂, ZrO₂, Sc₂O₃, AlNₓ, and Ga₂O₃.

In addition, as illustrated in FIG. 6, when the LED device 106 includes both the hole pushing film 81 and the electron pushing film 82, the electron pushing film 82 may be provided as an outermost film surrounding side surfaces of the first conductive semiconductor layer 10, photoactive layer 20, and second conductive semiconductor layer 30.

Furthermore, the hole pushing film 81 and the electron pushing film 82 may each independently have a thickness of 1 to 50 nm.

Meanwhile, the first conductive semiconductor layer 10, the photoactive layer 20, and the second conductive semiconductor layer 30 may be included as minimum components of the LED device, and another phosphor layer, quantum dot layer, active layer, semiconductor layer, hole block layer, and/or electrode layer may be further included on/below each layer.

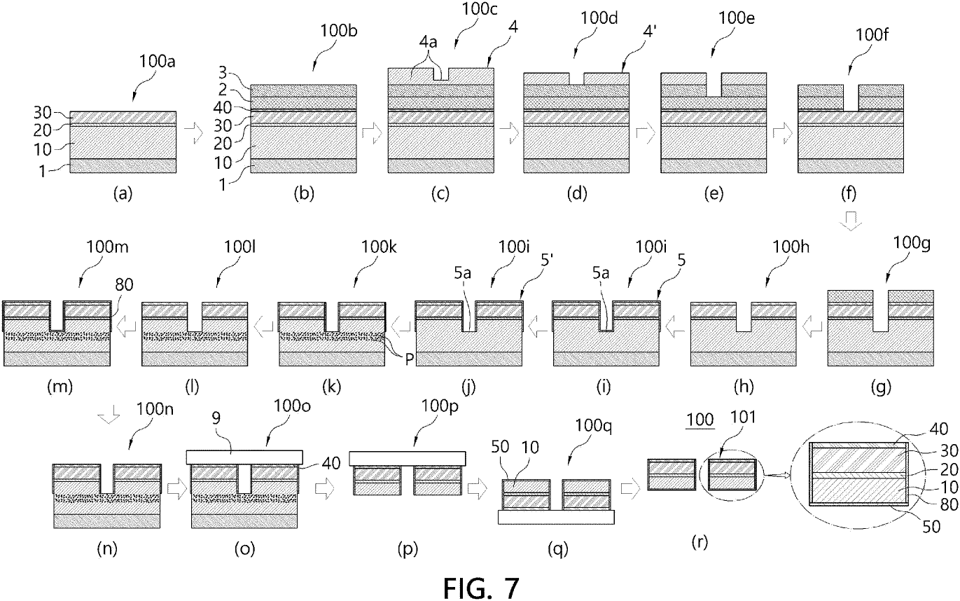

An LED aggregate 100 including the LED structure 101 according to an embodiment of the present invention described above may be manufactured through the manufacturing method shown in FIG. 7 .

Referring to FIG. 7, the LED aggregate 100 according to one embodiment of the present invention may be manufactured by including the steps of (1) preparing an LED wafer 100a (FIG. 7(a)), (2) patterning an upper portion of the LED wafer 100a such that a planar surface perpendicular to a direction in which layers are stacked in each LED structure has a desired shape and size (FIG. 7 (b) and (c)), and then vertically etching the conductive semiconductor layer 10 to at least a partial thickness thereof to form a plurality of LED structures (FIG. 7(d) to (h)), (3) forming a protective film so as to surround an exposed surface of each of the plurality of LED structures and expose upper surfaces of first portions between the adjacent LED structures to the outside (FIG. 7(i) to (j)), (4) immersing the LED wafer in an electrolyte, electrically connecting the LED wafer to one terminal of a power supply, electrically connecting the other electrode of the power supply to an electrode immersed in the electrolyte, and then applying power to form a plurality of pores in the first portions (FIG. 7(k)), and (5) applying ultrasonic waves to the LED wafer to separate the plurality of LED structures from the first portions in which the plurality of pores are formed (FIG. 7(o)).

A wafer that is commercialized and available may be used as the LED wafer 100a provided in step (1) without limitation. As an example, the LED wafer 100a may at least include a substrate 1, the first conductive semiconductor layer 10, the photoactive layer 20, and the second conductive semiconductor layer 30. In this case, the first conductive semiconductor layer 10 may be an n-type III-nitride semiconductor layer, and the second conductive semiconductor layer 30 may be a p-type III-nitride semiconductor layer. In addition, after the n-type III-nitride semiconductor layer is etched to a desired thickness, since the LED structures remain on the LED wafer after the etching may be separated through steps (3) to (5), a thickness of the n-type III-nitride semiconductor layer 10 in the LED wafer is also not limited, and the presence or absence of a separate sacrificial layer may not be considered when a wafer is selected.

In addition, each layer in the LED wafer 100a may have a c-plane crystal structure. In addition, the LED wafer 100a may be subjected to a cleaning process, and since a cleaning process and a cleaning solution of a typical wafer may be appropriately applied in the cleaning process, the present invention is not particularly limited thereto. The cleaning solution may be, for example, at least one selected from among isopropyl alcohol, acetone, and hydrochloric acid but is not limited thereto.

Next, before step (2) is performed, the step of forming the first electrode layer 40 on the p-type III-nitride semiconductor layer 30 may be performed. The first electrode layer 40 may be formed through a typical method of forming an electrode on a semiconductor layer and may be formed by, for example, deposition through sputtering. The material of the first electrode layer 40 may be, for example, ITO as described above, and the first electrode layer 40 may be formed to have a thickness of about 150 nm. The first electrode layer 40 may be further subjected to a rapid thermal annealing process after a deposition process. As an example, the first electrode layer 40 may be processed at a temperature of 600° C. for 10 minutes. However, since the rapid thermal annealing process may be appropriately adjusted in consideration of the thickness and material of the electrode layer, the present invention is not particularly limited thereto.

Next, in step (2), the upper portion of the LED wafer may be patterned such that the planar surface perpendicular to the direction in which the layers are stacked in each LED structure has the desired shape and size (FIG. 7(b) and (c)). Specifically, a mask pattern layer may be formed on an upper surface of the first electrode layer 40, and the mask pattern layer may be formed using a known method and material used in etching an LED wafer. A pattern of the pattern layer may be formed by appropriately applying a typical photolithography method or nanoimprinting method.

As an example, the mask pattern layer may be a stack of a first mask layer 2, a second mask layer 3, and a resin pattern 4′, which form a predetermined pattern on the first electrode layer 40 as illustrated in FIG. 7(f). To briefly describe a method of forming the mask pattern layer, as an example, the first mask layer 2 and the second mask layer 3 may be formed on the first electrode layer 40 through deposition, a resin layer 4, from which the resin pattern layer 4′ is derived, may be formed on the second mask layer 3 (FIG. 7(b) and 7(c)), a residual resin 4a of the resin layer 4 may be removed through a typical method such as a reactive ion etching (RIE) method, and then the second mask layer 3 and the first mask layer 2 may be sequentially etched (FIG. 7(e) and (f)) along a pattern of the resin pattern layer 4′ to form the mask pattern layer. In this case, the first mask layer 2 may be made of, for example, silicon dioxide, and the second mask layer 3 may be a metal layer made of aluminum, nickel, or the like. Meanwhile, when the first mask layer 2 is etched, the resin pattern layer 4′ may also be removed (FIG. 7(f)).

In addition, the resin layer 4, from which the resin pattern layer 4′ is derived, may be formed through a known nanoimprinting method. After a corresponding mold is manufactured on a desired predetermined pattern mold, the mold may be treated with a resin to form the resin layer 4, and then, the resin layer 4 may be transferred so as to be positioned on a wafer stack 100b in which the first mask layer 2 and the second mask layer 3 are formed on the first electrode layer 40, and then the mold 6 may be removed to implement a wafer stack 100c on which the resin layer 4 is formed.

Meanwhile, although a method of forming the pattern through the nanoimprinting method has been described, the present invention is not limited thereto, and a pattern may also be formed through known photolithography using a photosensitive material or may be formed through known laser interference lithography, electron beam lithography, or the like.

Thereafter, as illustrated in FIG. 7(g), the first conductive semiconductor layer 10, which is an n-type III-nitride semiconductor layer, may be vertically etched to a partial thickness in a direction perpendicular to a surface of an LED wafer 100f along a pattern of the mask layers 2, 3 formed on the first electrode layer 40, thereby forming an LED wafer 100 g on which the LED structures are formed. In this case, the etching may be performed through typical dry etching such as ICP and KOH/TMAH wet etching. In such an etching process, the second mask layer 3 made of Al constituting the mask pattern layer may be removed, and then, the first mask layer 2, which is made of silicon dioxide constituting the mask pattern layer present on the first electrode layer 40 of each LED structure in the LED wafer 100 g, may be removed to manufacture an LED wafer 100h on which the plurality of LED structures is formed.

Next, as step (3), the step of forming the protective film 80a to a predetermined thickness so as to surround the exposed surface of each of the plurality of LED structures in the LED wafer 100h on which the plurality of LED structures is formed and expose upper surfaces S1 of first portions a between the adjacent LED structures to the outside is performed (FIG. 7 (i) and (j)). The protective film 80a is for preventing damage to the LED structure due to the performing of step (4) to be described below. In addition, when the protective film 80a continues to remain on a side surface of the LED structure separated from the LED wafer, the protective film 80a may also perform a function of protecting a side surface of the individually separated LED structure from external stimuli.

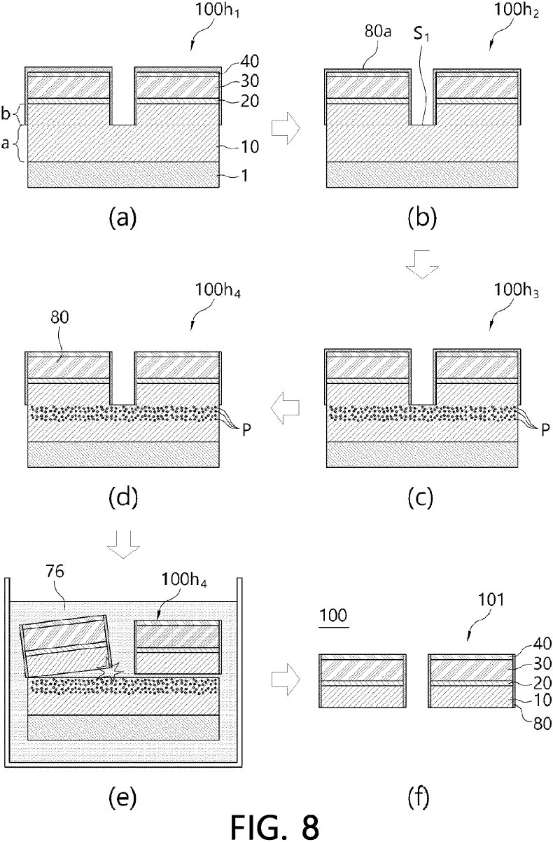

Describing steps (3) to (5) with reference to FIG. 8, specifically, step (3) may be performed by depositing a protective film material on the LED wafer 100h, on which the plurality of LED structures is formed, to form the protective film 80a to a predetermined thickness so as to surround the exposed surface of each of the plurality of LED structures (step 3-1) and removing the protective film deposited on the upper surfaces S1 of the first portions a between the adjacent LED structures to expose the upper surfaces S1 of the first portions a between the LED structures to the outside (step 3-2).

Step 3-1 is the step of depositing the protective film material on the LED wafer 100h on which the plurality of LED structures is formed (FIG. 8(a)). In this case, the protective film material may be a known material that is not chemically damaged by the electrolyte solution in step (4) to be described below. As an example, the above-described material of the protective film 80 may be used without limitation, and specifically, the protective film material may include at least one selected from among silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), lanthanum oxide (La₂O₃), scandium oxide (Sc₂O₃), titanium dioxide (TiO₂), aluminum nitride (AlN), and gallium nitride (GaN). In addition, the protective film 80a formed by depositing the protective film material may have a thickness of 5 to 100 nm and more preferably a thickness of 30 to 100 nm. When the thickness of the protective film 80a is less than 5 nm, it may be difficult to prevent the LED structure from being damaged by the electrolyte in step (4) to be described below, and when the thickness of the protective film 80a exceeds 100 nm, there may be problems in that manufacturing costs are increased and the LED structures are connected.

Next, Step 3-2 is the step of removing the protective film deposited on the upper surfaces S1 of the first portions a between the adjacent LED structures to expose the upper surfaces S1 of the first portions a between the LED structures to the outside (FIG. 8(b)). Due to the performing of step 3-1, the protective film material is also deposited on the upper surfaces S1 of the first portions a between the adjacent LED structures, and thus, since the electrolyte may not come into contact with the first conductive semiconductor layer 10 that is the n-type III-nitride semiconductor, desired pores may not be formed in the first portions a. Thus, the step of removing the protective film material applied on the upper surfaces S1 of the first portions a to expose the upper surfaces S1 of the first portions a to the outside may be performed, and in this case, the removing of the protective film material may be performed through a known dry or wet etching method in consideration of the protective film material.

Meanwhile, according to one embodiment of the present invention, the protective film 80a formed in step (3) may be a temporary protective film for preventing damage to the LED structure due to the performing of step (3), and after the temporary protective film is removed, the step of forming a surface protective film surrounding the side surface of the LED structure may be further included between steps (4) and (5). That is, as illustrated in FIG. 7, a protective film 5′ in step (3) may be provided only as a temporary protective film for preventing damage to the LED structure in step (4) (FIG. 7(i) to (k)), and a surface protective film 80, which performs a function of preventing damage to the surface of the LED structure after the temporary protective film is removed, may be formed to cover the side surface of the LED structure before step (5) is performed (FIG. 7(m)).

Meanwhile, in some embodiments as illustrated in FIG. 7, there is an inconvenience in that the protective film is formed twice, but the protective film may be selected in consideration of the planar shape and size of the LED structures to be manufactured, and the interval between the LED structures. In addition, when step (4) to be described below is performed, a protection film may be partially damaged, and since there may be a case in which, when the damaged protection film is left on the finally obtained individual LED structure and used as a surface protective film, it is difficult for the damaged protection film to properly perform a surface protection function, in some cases, it may be advantageous to remove a protective film subjected to step (4) and then provide a protective film again.

Describing such manufacturing processes illustrated in FIG. 7, after a temporary protective film material is deposited on the LED wafer 100h on which the plurality of LED structures is formed (FIG. 7(i)), the temporary protective film material 5, which is deposited on the upper surfaces S1 of the first portions a of the doped n-type III-nitride semiconductor layer 10 between adjacent LEDs of an LED wafer 100i on which the protective film material 5 is deposited, may be etched to form the protective film 5′ which is a temporary protective film that protects the side surfaces and upper portions of the plurality of LED structures. Next, after step (4) to be described below is performed (FIG. 7(k)), the protective film 5′ may be removed through etching (FIG. 7(1)), a protective film material may be deposited on the LED wafer 1001 as a surface protective film for protecting the surface of the LED structure, and then, the protective film material formed on each of the LED structures may be removed to form the protective film 80 surrounding the side surface of the LED structure (FIG. 7(m)). In this case, the protective film material formed on the LED structures may be removed together with the protective film material deposited on the upper surfaces S1 of the first portions a of the doped n-type III-nitride semiconductor layer 10 between adjacent LED structures of an LED wafer 100 m. Thus, in step (5) to be described below, a bubble-forming solution may come into contact with the upper surfaces S1 of the first portions a, and bubbles generated through ultrasonic waves may penetrate into pores P formed in the first portions a so that the LED structures may be separated through the bubbles.

Meanwhile, descriptions of the temporary protective film material and the surface protective film material are the same as those of the material of the above-described protective film, and an implemented film thickness may also be implemented within a thickness range of the above-described protective film.

Next, as step (4), the step of immersing the LED wafer in the electrolyte, electrically connecting the LED wafer to one terminal of the power supply, electrically connecting the other electrode of the power supply to the electrode immersed in the electrolyte, and then applying power to form the plurality of pores in the first portions is performed.

Specifically, referring to FIG. 8, an LED wafer 100 h₂ on which the protective film 80a is formed may be electrically connected to one terminal of the power supply, for example, an anode, and the other terminal of the power supply, for example, a cathode, may be electrically connected to the electrode immersed in the electrolyte, and then, power may be applied, thereby manufacturing an LED wafer 100 h₃ in which the plurality of pores P is formed in the first portions a of the first conductive semiconductor layer 10 which is a doped n-type III-nitride semiconductor. In this case, the pores P may start to be formed from the upper surface S1 of the first portions a of the first conductive semiconductor layer 10, which is the doped n-type III-nitride semiconductor, in direct contact with the electrolyte, and may be formed in a thickness direction and a direction toward a side surface of the first portion a corresponding to a lower portion of each of the LED structures.

The electrolyte used in step (4) may include at least one oxygen acid selected from the group consisting of an oxalic acid, a phosphoric acid, a sulfurous acid, a sulfuric acid, a carbonic acid, an acetic acid, a chlorous acid, a chloric acid, a bromic acid, a nitrous acid, and a nitric acid, and more preferably, oxalic acid may be used. Therefore, there is an advantage in that damage to the first conductive semiconductor layer can be minimized. In addition, the electrode may be made of platinum (Pt), carbon (C), nickel (Ni), gold (Au), or the like and may be, for example, a platinum electrode. In addition, in step (4), a voltage of 3 V or more may be applied as power for 1 minute to 24 hours, and thus, the pores P can be smoothly formed up to the first portion a corresponding to the lower portion of each of the plurality of LED structures. Accordingly, the LED structure can be more easily separated from the wafer through step (5). More preferably, a voltage of 10 V or more may be applied, and more preferably, a voltage of 30 V or less may be applied. When a voltage of less than 3 V is applied, even when an application time of power is increased, pores may not smoothly formed in the first portion a corresponding to the lower portion of each of the LED structures, and thus, it may be difficult to separate the LED structures through step (5) to be described below, or even though the LED structures are separated, separated one cross sections of the plurality of LED structures may have different shapes, which may make it difficult for the plurality of LED structures to exhibit uniform characteristics. In addition, when a voltage exceeding 30 V is applied, pores may be formed up to a second portion b which is a lower end portion of the LED structure connected to the first portion a of the doped n-type III-nitride semiconductor layer, thereby causing the deterioration of luminescent properties. In addition, it is preferable that the separation of the LED structure in step (5) to be described below is performed at a boundary point between the first portion a of the doped n-type III-nitride semiconductor layer and the second portion b, but due to pores formed in the second portion b, separation may occur at any point of the second portion b beyond the boundary point, which may cause a risk of obtaining an LED structure including an n-type semiconductor layer with a thickness less than that of an initially designed n-type semiconductor layer. In addition, similarly to an effect according to a strength of a voltage, when an application time of power is increased, pores are likely to be formed in the second portion b other than a desired portion, and on the contrary, when the application time is decreased, pores may not be smoothly formed, and thus, it may be difficult to separate the LED structures.

After step (4) and before step (5) to be described below, the step of manufacturing an LED wafer 100h4, in which the protective film formed on an upper surface of each of the LED structures among the protective films 80a is removed to enable an electrical connection toward the first electrode layer 40 after the LED structure is separated from a wafer, may be further performed. In addition, since only the protective film formed on the upper surface of the LED structure is removed, the protective film 80 formed on the side surface of the LED structure may remain to perform a function of protecting the side surface of the LED structure from the outside.

In addition, after step (4) and before step (5) to be described below, the step of forming another layer on the first electrode layer 40 of the LED structure may be further performed, and another layer may be, for example, a Ti/Au composite layer.

Next, as step (5), the step of applying ultrasonic waves to the LED wafer (100h4 in FIG. 8(e)) to separate the plurality of LED structures from the first portions a in which the plurality of pores P is formed is performed.

In this case, the ultrasonic wave may be applied directly to the LED wafer 100 h4 in which pores are formed or may be applied indirectly by immersing the LED wafer 100 h4 in which the pores are formed, in a solvent. However, in a method of collapsing the pores P of the first portion a using an external physical force caused by the ultrasonic wave itself, the collapse of the pores is not smooth, and when the pores are excessively formed to facilitate the collapse, the pores are likely to be formed up to the second portion b of the LED structure, which may cause a side effect of reducing the quality of the LED structure.

Accordingly, according to one embodiment of the present invention, step (5) may be performed using a sonochemical method. Specifically, after the LED wafer 100h4 (FIG. 8(e)) is immersed in a bubble-forming solution (or solvent) 76, ultrasonic waves are applied to the bubble-forming solution (or solvent) 76 to collapse the pores through energy generated when bubbles generated and grown through a sonochemical mechanism burst in the pores, thereby separating the plurality of LED structures. Specifically, ultrasonic waves alternately generate a relatively high pressure portion and a relatively low pressure portion in a traveling direction of a sound wave. In this case, generated bubbles pass through the high pressure portion and the low pressure portion and repeatedly contract and expand to grow into bubbles with a higher temperature and high pressure and then collapse, and when the bubbles collapse, as an example, the bubbles become local hot spots that generate a high temperature of 4,000 K and a high pressure of 1,000 atmospheric pressure. Therefore, by using such energy, the pores generated in the LED wafer may be collapsed to separate the LED structure from the wafer. After all, the ultrasonic wave only performs a function of generating and growing bubbles in the bubble-forming solution (or solvent) and moving and allowing the generated bubbles to penetrate into the pores P of the first portion a. Then, through a pore collapse mechanism in which the pores P are collapsed by an external force generated at the time of the bursting of the bubbles in an unstable state with a high temperature and high pressure, which have penetrated into the pores P, the plurality of LED structures may be easily separated from the LED wafer, thereby obtaining an LED aggregate 100′ including a plurality of LED structures 101′.

A solution (or solvent) capable of generating bubbles when ultrasonic waves are applied and growing to have high pressure and temperature may be used as the bubble-forming solution (or solvent) 76 without limitation, and preferably, the bubble-forming solution (or solvent) may have a vapor pressure of 100 mmHg or less (at 20° C.), for example, a vapor pressure of 80 mmHg or less (at 20° C.), a vapor pressure of 60 mmHg or less (at 20° C.), a vapor pressure of 50 mmHg or less (at 20° C.), a vapor pressure of 40 mmHg or less (at 20° C.), a vapor pressure of 30 mmHg or less (at 20° C.), a vapor pressure of 20 mmHg or less (at 20° C.), or a vapor pressure of 10 mmHg or less (at 20° C.). When a solvent having a vapor pressure exceeding 100 mmHg (at 20° C.) is used, separation may not occur properly within a short time, and thus there is a risk of a manufacturing time being increased and production costs being increased. The bubble-forming solution 76 satisfying such physical properties may include, for example, at least one selected from the group consisting of gamma-butyllactone, propylene glycol methyl ether acetate, methyl pyrrolidone, and 2-methoxyethanol. Meanwhile, a solution (or solvent) having a vapor pressure of 100 mmHg at room temperature, for example, 20° C., may be used as the bubble-forming solution (or solvent), but alternatively, by adjusting conditions for performing step (5), step (5) may be performed by adjusting a vapor pressure of the bubble-forming solution (or solvent) so as to be 100 mmHg or less under the above conditions (for example, low temperature conditions). In this case, types of usable solvents may be wider, and as an example, solvents such as water, acetone, chloroform, and alcohols may be used.

In addition, a wavelength of an ultrasonic wave applied in step (5) may be in a range capable of causing a sonochemical effect, and specifically, the ultrasonic wave may be applied at a frequency capable of growing and collapsing bubbles so as to become local hot spots that generate high pressure and temperature when collapsed. As an example, the frequency may be in a range of 20 kHz to 2 MHz, and an application time of the applied ultrasonic wave may be in a range of 1 minute to 24 hours, thereby making it easy to separate the LED structure from the LED wafer. Even when a wavelength of an applied ultrasonic wave falls within the range, when an intensity of the applied ultrasonic wave is low or an application time thereof is short, there is a risk that there are LED structures that are not separated from the LED wafer or that the number of the LED structures that are not separated from the LED wafer is increased. In addition, when the intensity of the applied ultrasonic wave is high or the application time is long, the LED structure may be damaged.

Meanwhile, in order to form the second electrode layer 50 on the first conductive semiconductor layer 10, before step (5) is performed, the step of attaching a support film 9 onto an LED wafer 100n to form another layer, for example, the second electrode layer 50 or an electron delay layer (not shown) on the first conductive semiconductor layer 10 may be further performed (see FIG. 7(o)), and thus, the plurality of LED structures in a state in which the support film 9 is attached may be separated from the LED wafer (see FIG. 7(p)). After that, in a state in which the support film 9 is attached, the second electrode layer 50 may be formed on the plurality of LED structures through a known method such as a deposition method (FIG. 7(q)), and then, the support film may be removed, thereby obtaining an aggregate 100 of a plurality of LED structures 101.

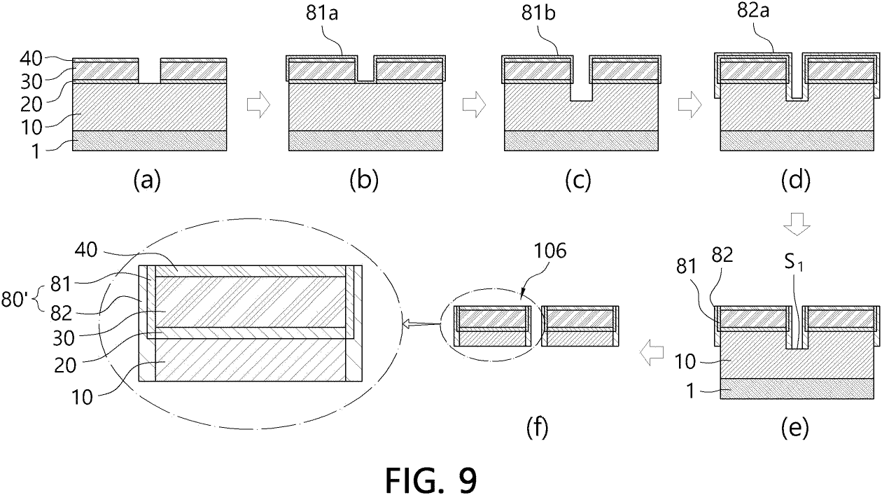

Meanwhile, as described above with reference to FIG. 6, the protective film 80′ including the hole pushing film 81 and the electron pushing film 82 for improving luminous efficiency as a protective film may be formed, and a manufacturing method thereof will be described with reference to FIG. 9.

There is a difference from those described above with reference to FIG. 7 in that processes of, during vertical etching, without performing etching down to a portion of the first conductive semiconductor layer 10 which is an n-type semiconductor, primarily etching only the second conductive semiconductor layer 30 or only a portion of the second conductive semiconductor layer 30 and photoactive layer 20, or only the photoactive layer 20 (FIG. 9(a)), secondarily etching the first conductive semiconductor layer 10 to a partial thickness thereof (FIG. 9(c)), depositing a film material, and removing the film material between a plurality of LED structures are performed twice (FIG. 9(b), (d), (e)).

Specifically, processes of, when an LED wafer is vertically etched, without performing etching down to a portion of the first conductive semiconductor layer 10 which is the n-type semiconductor, primarily etching only the second conductive semiconductor layer 30, or an entirety of the second conductive semiconductor layer 30 and a portion of the photoactive layer 20, or only the photoactive layer 20 (FIG. 9(a)), depositing a hole pushing film material 81a (FIG. 9(b)), and then, removing a hole-repellent material formed between the LED structures are performed. After that, process of secondarily etching the first conductive semiconductor layer 10 again to a predetermined thickness thereof (FIG. 9(c)), depositing an electron pushing film material 82a on the LED structure on which the hole pushing film 81b is formed (FIG. 9(d)), and then, removing an electron-repellent material formed on an upper surface S₁ between the LED structures again (FIG. 9(e)) may be performed. Thereafter, a process of separating the LED structure (FIG. 7(k) and subsequent drawing) as described above with reference to FIG. 7 or a process of separating the LED structure in FIG. 8 (FIG. 8(d) and subsequent drawings) may be performed to separate an LED structure 106 from the LED wafer.

The LED structure 101,102,103,104,105,106 obtained through the above-described methods may be implemented with an ink composition for inkjet. The ink composition may further include a dispersion medium and other additives which are provided in a known ink composition for inkjet, and the present invention is not particularly limited thereto.

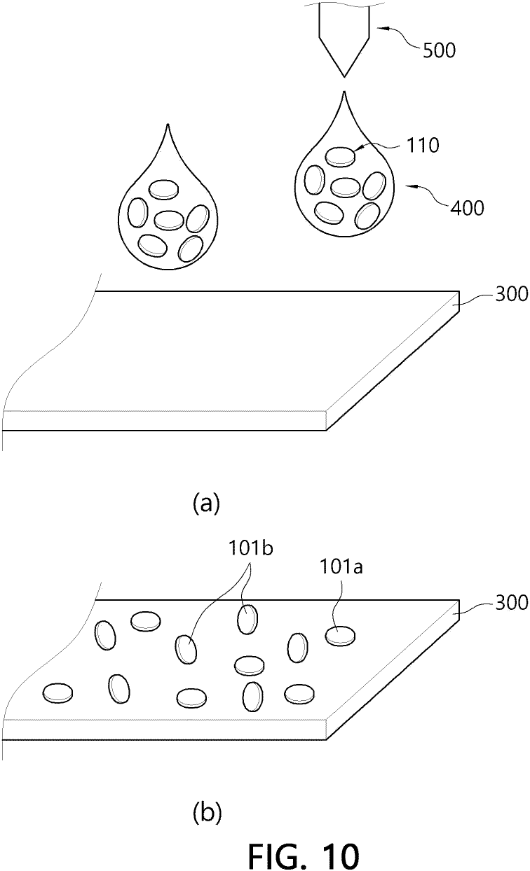

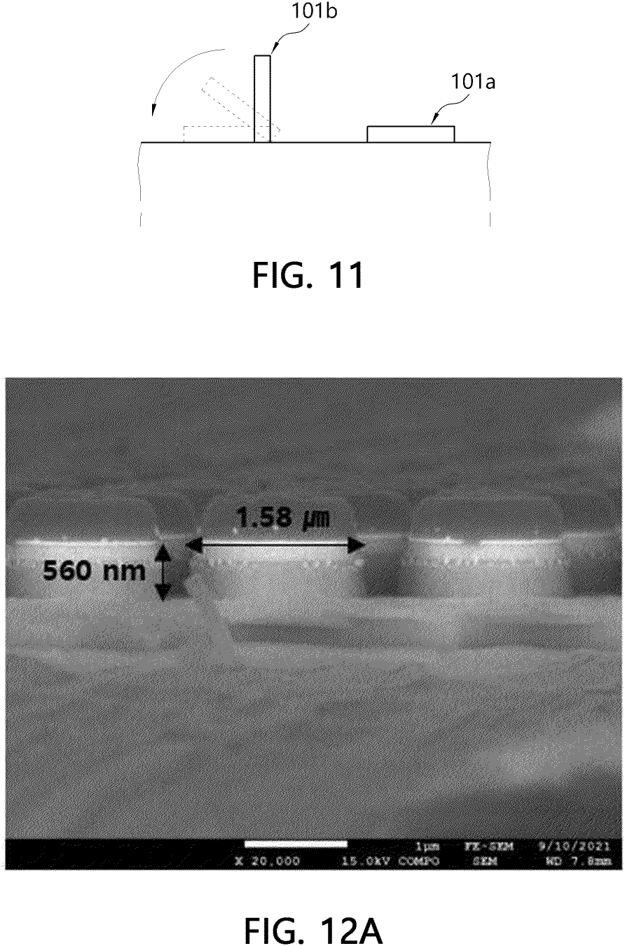

As illustrated in FIG. 10(a), an ink composition 400 containing a plurality of LED structures 101 according to the present invention may be treated on an electrode 300 through a nozzle, for example, a nozzle 500 of an inkjet printer. In this case, the plurality of LED structures 101 contained in one ink droplet is discharged from the nozzle 500 and then the ink droplet touches the electrode 300, and may be precipitated or free-precipitated toward the surface of the electrode 300 until a dispersion medium 410 in the ink composition is all volatilized. Thereafter, as illustrated in FIG. 10(b), the LED structures 101a, 101b are aligned on the upper surface of the electrode 300, and most of the LED structures may be aligned so that the target surfaces are in contact with the upper surface of the electrode 300 as illustrated. On the other hand, in the case of some LED structures 101b, the side surfaces may be aligned so as to contact the upper surface of the electrode 300, and as the distance between the two target surfaces is implemented to be thin, as illustrated in FIG. 11, the alignment surface may be modified so that the target surfaces are in contact with the upper surface of the electrode 300 only by applying a physical external force such as a slight vibration. Thus, the LED structures may be self-aligned so that the target surfaces can be easily positioned on the electrode without applying an electric or magnetic field.

In addition, according to the present invention, a light source including the LED structure 101,102,103,104,105,106 described above is included. The light source may include, for example, various LED lights for home/vehicle, a light emitting source of various displays such as a backlight unit employed in LCD or a light emitting source of an active display, medical devices, beauty devices, various optical devices, or one component constituting the same.

The present invention will be described in more detail through the following Examples, but the following Examples do not limit the scope of the present invention, and it should be understood that the following Examples are intended to assist the understanding of the present invention.

### Example 1

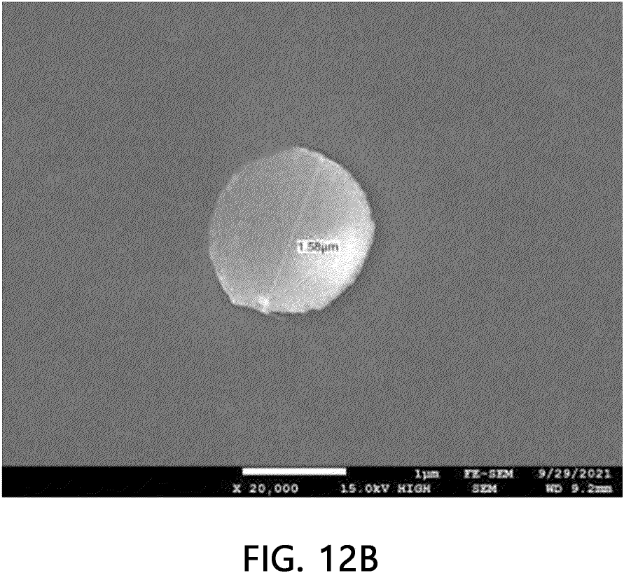

A typical LED wafer (manufactured by Epistar Corporation), in which an undoped n-type III-nitride semiconductor layer, an n-type III-nitride semiconductor layer doped with Si (with a thickness of 4 µm), a photoactive layer (with a thickness of 0.45 µm), and a p-type III-nitride semiconductor layer (with a thickness of 0.05 µm) were sequentially stacked on a substrate, was prepared. ITO (with a thickness of 0.15 µm) as a first electrode layer, SiO₂ (with a thickness of 1.2 µm) as a first mask layer, and Al (with a thickness of 0.2 µm) as a second mask layer were sequentially deposited on the prepared LED wafer, and then a spin-on-glass (SOG) resin layer onto which a pattern is transferred was transferred onto the second mask layer using nanoimprint equipment. Thereafter, the SOG resin layer was cured using RIE, and a residual resin portion of the resin layer was etched through RIE to form a resin pattern layer. After that, a second mask layer was etched using ICP according to the pattern, and a first mask layer was etched using RIE. Next, after the first electrode layer, the p-type III-nitride semiconductor layer, and the photoactive layer were etched using ICP, the doped n-type III-nitride semiconductor layer was etched to a thickness of 0.78 µm, and then, an LED wafer, in which a plurality of LED structures (with an area of target surface of 1.96 µm², and an etching depth t of 580 nm) (FIG. 12(a)) was formed through KOH wet etching so as to implement a side surface of the etched doped n-type III-nitride semiconductor layer so as to be perpendicular to a layer surface, was manufactured. After that, a SiNₓ protective film material was deposited on the LED wafer on which the plurality of LED structures was formed (deposition thicknesses of 52.5 nm from a side surface of the LED structure), and then, the protective film material formed between the plurality of LED structures was removed through a reactive ion etcher to expose an upper surface S₁ of a first portion a of the doped n-type III-nitride semiconductor layer.

Then, the LED wafer on which a temporary protective film was formed was immersed in an electrolyte solution of 0.3 M oxalic acid and connected to an anode terminal of a power supply, a cathode terminal was connected to a platinum electrode immersed in the electrolyte, and then, a voltage of 10 V was applied for 5 minutes to form a plurality of pores from the surface of the first portion a of the doped n-type III-nitride semiconductor layer to a depth of 680 nm. Next, after the temporary protective film was removed through RIE, a surface protective film made of Al₂O₃ was deposited again on the LED wafer to a thickness of 50 nm from the side surface of the LED structure, the surface protective film formed on the upper portions of the plurality of LED structures and the surface protective film formed on the upper surface S₁ of the first portion a of the doped n-type III-nitride semiconductor layer were removed through ICP to expose the upper surface S₁ of the first portion a of the semiconductor layer and an upper surface of the LED structure. Next, after the LED wafer was immersed in a bubble-forming solution of gamma-butyllactone, ultrasonic waves were radiated at a frequency of 40 kHz for 10 minutes to collapse the pores formed in the doped n-type III-nitride semiconductor layer using generated bubbles and separate the plurality of LED structures from the wafer, thereby manufacturing an LED aggregate including the LED structures as in FIG. 12(b). Meanwhile, it was confirmed through SEM imaging that there was no unseparated LED structure on the wafer remaining after the separation process.

When the LED structure according to the present invention touches the ground after free fall in air or vacuum or free precipitation in liquid, the probability that the target surface of the structure touches the ground is very high, and even if a surface other than the target surface touches the ground, the target surface can easily touch the ground due to the spontaneous fall of the structure or a weak vibration, so it is possible to omit the additional process for self-aligning the LED structure on the electrode. Accordingly, when the LED structure is inked and processed on the electrode, it is possible to prevent contact failure caused by the undesired surface of the LED structure touching the electrode, and the LED structure can be easily mounted so that the desired surface touches the electrode, so LED electrode assembly can be easily implemented. In addition, due to the structure of the LED structure, it is advantageous in achieving high luminance and luminous efficiency by increasing an emission area as compared with a conventional rod-type LED element. In addition, an emission area is increased, and also, an area of an exposed surface of a photoactive layer is greatly reduced, thereby preventing or minimizing a degradation in efficiency due to surface defects. Furthermore, it is possible to minimize a degradation in electron-hole recombination efficiency due to non-uniformity of electron and hole velocities and a resulting degradation in luminous efficiency. Due to the above-described advantages, the LED structure according to the present invention can be widely applied as a material for various light sources such as displays.

While the embodiments of the present invention have been described above, the spirit of the present invention is not limited to the embodiment presented herein. One skilled in the art may easily suggest other embodiments due to addition, modification, deletion, inclusion, and the like of components within the same spirit of the present invention, and the addition, modification, deletion, inclusion, and the like of the components fall within the scope and spirit of the present invention.

What is claimed is:

1. An LED structure in which layers comprising a first conductive semiconductor layer, a photoactive layer, and a second conductive semiconductor layer are stacked, wherein in order that any one of two opposite target surfaces of the LED structure perpendicular to a stacking direction of the layers becomes a contact surface with respect to a ground when the LED structure is freely precipitated, a ratio S/t of an area S of any one of the target surfaces and a distance t between the two target surfaces satisfies 1.5 or more.

2. The LED structure according to claim 1, wherein one of the first conductive semiconductor layer and the second conductive semiconductor layer is an n-type III-nitride semiconductor layer, and the other one is a p-type III-nitride semiconductor layer.

3. The LED structure according to claim 1, wherein when one of the two target surfaces is a first target surface and the other is a second target surface, an area ratio of the first target surface and the second target surface is 1: 0.1 to 10.

4. The LED structure according to claim 1, wherein the areas of the two target surfaces are each independently 0.2 to 100 µm².

5. The LED structure according to claim 1, wherein the distance t between the two target surfaces is 0.3 to 3.5 µm.

6. The LED structure according to claim 1, wherein the first conductive semiconductor layer is an n-type III-nitride semiconductor layer, and the LED structure further comprises an electron delay layer below the first conductive semiconductor layer so that numbers of electrons and holes recombined in the photoactive layer are balanced.

7. The LED structure according to claim 6, wherein the electron delay layer includes at least one selected from the group consisting of CdS, GaS, ZnS, CdSe, CaSe, ZnSe, CdTe, GaTe, SiC, ZnO, ZnMgO, SnO₂, TiO₂, In₂O₃, Ga₂O₃, silicon (Si), poly(paraphenylene vinylene) and derivatives thereof, polyaniline, poly(3-alkylthiophene), and poly(paraphenylene).

8. The LED structure according to claim 6, wherein the first conductive semiconductor layer is a doped n-type III-nitride semiconductor layer, and the electron delay layer is a III-nitride semiconductor having a doping concentration lower than that of the first conductive semiconductor layer.

9. The LED structure according to claim 1, further comprising a protective film configured to surround an exposed side surface of the LED structure.

10. The LED structure according to claim 1, wherein the first conductive semiconductor layer is an n-type III-nitride semiconductor layer, the second conductive semiconductor layer is a p-type III-nitride semiconductor layer, and
wherein the LED structure further comprises at least any one film of a hole pushing film configured to surround an exposed side surface of the second conductive semiconductor layer or the exposed side surface of the second conductive semiconductor layer and an exposed side surface of at least a portion of the photoactive layer and move holes at a surface side of the exposed side surface toward a center, and an electron pushing film configured to surround an exposed side surface of the first conductive semiconductor layer and move electrons at a surface side of the exposed side surface toward a center.

11. The LED structure according to claim 10, wherein the LED structure comprises both the hole pushing film and the electron pushing film, the electron pushing film is provided as an outermost film configured to surround side surfaces of the first conductive semiconductor layer, photoactive layer, and second conductive semiconductor layer.

12. The LED structure according to claim 10, wherein the hole pushing film includes at least one selected from the group consisting of A1Nₓ, ZrO₂, MoO, Sc₂O₃, La₂O₃, MgO, Y₂O₃, Al₂O₃, Ga₂O₃, TiO₂, ZnS, Ta₂O₅, and n-MoS₂, and the electron pushing film includes at least one selected from the group consisting of Al₂O₃, HfO₂, SiNₓ, SiO₂, ZrO₂, Sc₂O₃, AlNₓ, and Ga₂O₃.

13. The LED structure according to claim 1, further comprising a second electrode layer provided on the first conductive semiconductor layer and a first electrode layer provided on the second conductive semiconductor layer.

14. An ink composition for inkjet, comprising a plurality of the LED structures according to claim 1.

15. A light source which is equipped with the LED structure according to claim 1.
